(19) United States
(12) Patent Application Publication
(10) Pub. No.: US 2021/0239292 A1
(43) Pub. Date: Aug. 5, 2021

(54) ILLUMINATION DEVICE FOR VEHICLES

(71) Applicant: HELLA GmbH & Co. KGaA, Lippstadt (DE)

(72) Inventors: Markus GIEHL, Lippstadt (DE); Daniela KARTHAUS, Lippstadt (DE); Franziska KLEY, Geseke (DE)

(73) Assignee: HELLA GmbH & Co. KGaA, Lippstadt (DE)

(21) Appl. No.: 17/239,106

(22) Filed: Apr. 23, 2021

Related U.S. Application Data
(63) Continuation of application No. PCT/EP2019/077611, filed on Oct. 11, 2019.

(30) Foreign Application Priority Data
Oct. 23, 2018 (DE) 10 2018 126 297.3

(51) Int. Cl. F21S 41/20; F21S 41/143

(52) U.S. Cl. CPC F21S 41/285; H01L 33/505; F21S 41/143

(57) ABSTRACT

An illumination device for vehicles for illuminating a roadway region in front of the vehicle, the device comprising a housing which is closed by a transparent cover panel and in which a light source unit is arranged for generating a light beam and in which an optical unit is arranged for shaping the light beam according to a specified light distribution to be generated outside the housing, wherein the optical unit has a divergence corrector for the light beam, wherein the divergence corrector on a side facing away from the light source has a structural surface having a plurality of structural elements in the micro and/or nano and/or atomic length range, and the structural surface is arranged directly on or near to a light-emitting surface of the light source.

This nonprovisional application is a continuation of International Application No. PCT/EP2019/077611, which was filed on Oct. 11, 2019 and which claims priority to German Patent Application No. 10 2018 126 297.3, which was filed in Germany on Oct. 23, 2018 and which are both herein incorporated by reference.

### BACKGROUND OF THE INVENTION

### Field of the Invention

The present invention relates to an illumination device for vehicles for illuminating a roadway region in front of the vehicle, said device comprising a housing which is closed by a transparent cover panel and in which a light source unit is arranged for generating a light beam and in which an optical unit is arranged for shaping the light beam according to a specified light distribution to be generated outside the housing, wherein the optical unit has a divergence corrector for the light beam.

### Description of the Background Art

In the case of light source units with light sources designed as LEDs, there is the problem that the LEDs emit light in a relatively large solid angle due to their Lambertian emission characteristics. Primary optical elements are necessary in order to collect the light and to supply it to light-imaging elements, for example, a lens device, in order to generate a specified light distribution. As a primary optical element which as a divergence corrector corrects the divergence or sets a precise divergence angle, a light guide is known, for example, from DE 103 19 274 A1, which corresponds to US 2004/0264185 on the light output side of which the light beam is emitted at an opening angle of 9°. U.S. Pat. No. 5,816,681 A provides a Fresnel plate as a divergence corrector, which is arranged at a distance from the light source unit. EP 2 467 635 B1 provides lenses as divergence corrector, which are arranged at a distance from the light sources. The disadvantage of the known illumination devices is that the known measures for divergence correction require a relatively large amount of installation space.

### SUMMARY OF THE INVENTION

It is therefore an object of the present invention to provide an illumination device for vehicles such that the divergent emission of a light beam is effectively corrected or adjusted in a simple manner, with the saving of space, so that a specified light distribution can be generated by further downstream opticals.

To achieve said object, the invention is characterized in that the divergence corrector on a side facing away from the light source has a structural surface having a plurality of structure elements in the micro and/or nano and/or atomic length range, and in that the structural surface is arranged directly on or near a light-emitting surface of the light source.

According to the invention, the divergence corrector is designed as a divergence corrector which has a structural surface in a micro and/or nano and/or atomic length range. The thus formed structural elements of the divergence corrector are arranged directly on a light output surface of the light source or in the vicinity of the same. The divergence corrector is advantageously arranged close to the light source, so that it can form a mutual structural unit together with the light source. The divergence corrector is virtually a component of the light source unit. The installation space can advantageously be significantly reduced. In particular, the small extent of the structural elements can be used advantageously when illuminating small areas or when coupling into relatively narrow light guides. By changing the direction of light directly at the light source, the light emitted by the light source can be specifically deflected and precisely adjusted according to a specified divergence angle. In particular, stray light can advantageously be reduced.

A thickness of the divergence corrector can be less than 2 mm and/or corresponds to a thickness of a substrate of the divergence corrector. The thickness of the divergence corrector is substantially determined by the substrate which has the structural elements. The installation space in the main emission direction can thus advantageously be kept small.

The divergence corrector can have a transverse extent to the main emission direction of the light source, which is equal to or at most 1.5 times a width of the light-emitting surface of the light source. Advantageously, due to the proximity to the light-emitting surface of the light source, the divergence corrector can substantially correspond to the transverse extent of the light-emitting surface of the light source, so that the installation space is not increased in width.

The structural elements can have a maximum height relative to a base area of the same in the micro and/or nano and/or atomic length range. The structural elements thus have relatively small distances both in the main emission direction and in the direction perpendicular to the main emission direction.

The divergence corrector can be arranged at a distance of at most 2 mm from the light-emitting surface of the light source. The dimensioning of the structural elements is adapted to the distance thereof from the light-emitting surface of the light source.

The structural surface of the divergence corrector can form the light-emitting surface of the light source. It is therefore an integral part of the light source, which results in a high degree of effectiveness in terms of setting a fixedly specified divergence angle.

The structural surface can be arranged together with the substrate at a distance from the light-emitting surface of the light source, wherein the divergence angle can be adjusted by defining the distance.

The structural elements can be fixedly connected to a housing of the light source via a housing of the divergence corrector. The substrate of the divergence corrector is preferably connected to the housing of the light source. A clear relative position of the structural elements to the light-emitting surface of the light source can advantageously be created by precision fastener.

The substrate of the divergence corrector can be formed of a material that converts light source light, therefore, of a material by means of which the light from the light source is converted into white light. If, for example, a semiconductor crystal of the light source emits blue light, the substrate can be formed of a phosphor material that converts the blue light into white light.

The divergence corrector can have a surface structuring on a side facing the light source for the additional shaping of the light beam. Advantageously, the light shaping can be further optimized thereby.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic illustration of a light source unit with a divergence corrector according to a first embodiment;

FIG. 2 shows a schematic illustration of a light source unit with a divergence corrector according to a second embodiment;

FIG. 3 shows a schematic illustration of a light source unit with a divergence corrector according to a third embodiment;

FIG. 4 shows a schematic illustration of a light source unit with a divergence corrector according to a fourth embodiment; and

FIG. 5 shows a schematic illustration of a light source unit with a divergence corrector according to a fifth embodiment.

### DETAILED DESCRIPTION

An illumination device of the invention for vehicles is preferably used as a headlight for generating different light distributions, for example, a low beam, city light, or highway light distribution, or the like. For this purpose, the illumination device has a light source unit 1 with one or more semiconductor-based light sources 2 and an optical unit for shaping the light beam in accordance with the specified light distribution. Light source unit 1 and the optical unit are arranged in a mutual housing which is closed by a transparent cover panel. For light shaping or light distribution, the optical unit can have a light guide and/or a lens device and/or a liquid crystal device and/or a microlens device and/or a device with one or a plurality of micromirrors, each of which is arranged downstream in the light path or in the main emission direction H in front of light source unit 1. Further, the optical unit comprises a divergence corrector 3 described below. Divergence corrector 3 is a component of or forms a primary optics by means of which light preforming takes place. Light preforming serves in particular to optimally illuminate a secondary optics of the optical unit, optics that are located downstream of the primary optics. The secondary optics are designed such that the specified light distribution is generated. Divergence corrector 3 is used for preforming and/or for divergence angle correction and can also be used, for example, in the interior of vehicles, in signal lights, rear lights, or other lights.

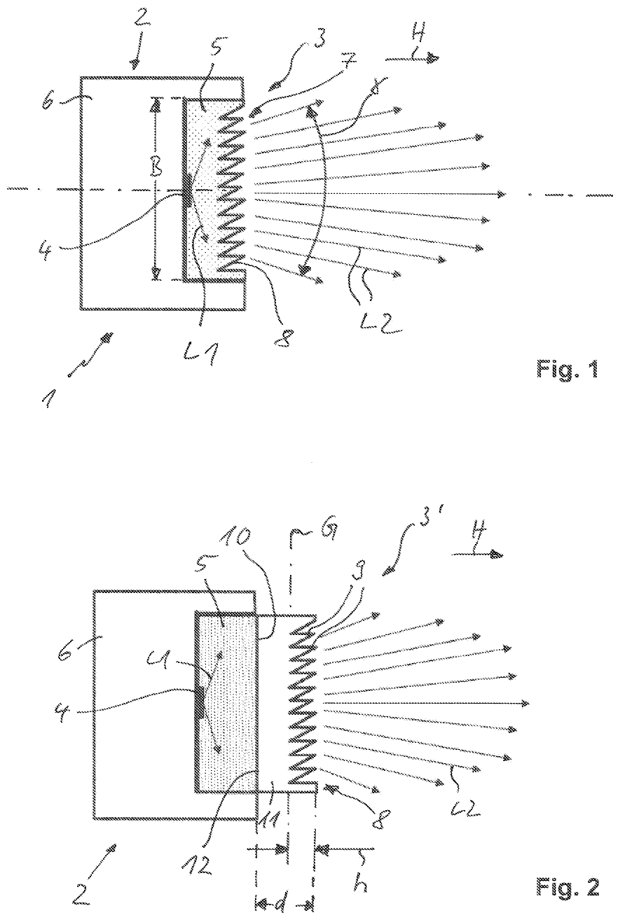

According to a first embodiment of the invention according to FIG. 1, light source 2 has a phosphor-converting light-emitting diode 4, in which the light L1 emitted by light-emitting diode 4, usually blue light, strikes a downstream phosphor 5, usually a phosphor converting into yellow light, and is partially converted into yellow conversion light. This yellow conversion light, together with the unconverted blue component, results in white light which is emitted as a light beam L2 in the direction of the downstream optical elements (not shown) of the optical unit. Light emitting diode 4 emits light L1 in accordance with Lambertian emission characteristics. Light source 2 thus has light-emitting diode 4 and phosphor 5. Light-emitting diode 5 can alternatively also be another light-emitting semiconductor element.

According to an alternative embodiment of the invention, which is not shown, light-emitting diode 4 can also be formed as a directly emitting light-emitting diode, which emits white light.

As can be seen from FIG. 1, light-emitting diode (semiconductor crystal) 4 and phosphor 5 are enclosed in a housing 6 of light source 2. A front surface 7 of phosphor 5 in the main emission direction H of light source 2 is formed as a structural surface 8 of divergence corrector 3. In this case, divergence corrector 3 is part of light source 2.

Structural surface 8 has a structure dimensioning such that light beam L1 is emitted at a specified divergence angle y (opening angle). Light beam L2 is preferably emitted rotationally symmetrically to an axis A of light source 2.

Structural surface 8 has a plurality of structural elements 9 arranged in a plane running perpendicular to axis A, so that there is a structuring in the micrometer and/or nanometer and/or atomic length range. This means that the distance between adjacent structural elements 9 is within said micro or nano or atomic length range. In the figures, structural elements 9 are not shown to scale for better visibility.

The dimension of structural surface 8 corresponds to a light-emitting surface 10 of light source 2. The transverse extent of structural surface 8 or of divergence corrector 3 thus corresponds to a width B of light-emitting surface 10 of light source 2.

With regard to a base area G of structural surface 8, structural elements 9 each have a height h in the millimeter and/or micrometer range, see FIG. 2 by way of example.

According to a second embodiment according to FIG. 2, a divergence corrector 3′ is provided which has a substrate 11 made of a transparent material, on which structural surface 8 with structural elements 9 is arranged on a front side facing away from light source 2. A preferably planar rear side 12 of substrate 11 abuts directly a planar front side of phosphor 5 of light source 2. In contrast to the embodiment according to FIG. 1, divergence corrector 3′ does not end flush with a front side of housing 6 but protrudes from housing 6 of light source 2. Divergence corrector 3′ thus directly adjoins light source 2. It has a thickness d which is in a range between 1 mm and 5 mm. The thickness d thus essentially corresponds to the thickness of substrate 11.

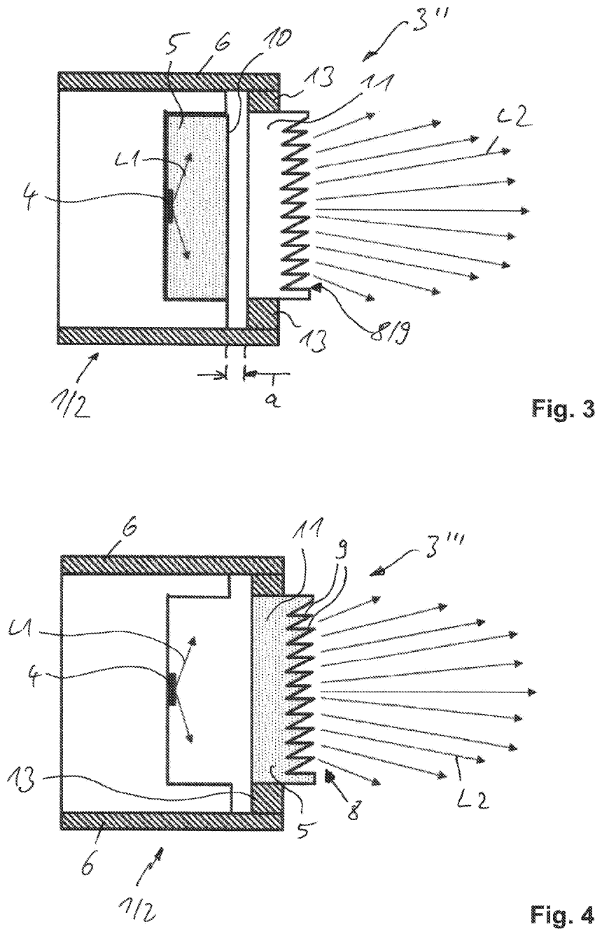

According to a further embodiment of the invention according to FIG. 3, a divergence corrector 3″ is provided which, compared to the embodiment according to FIG. 2, additionally has a housing 13 which is fixedly connected to housing 6 of light source 2 via a fastener. Here, housing 13 serves as a type of holding device for divergence corrector 3″. The connection of the two housings 6, 13 can take place, for example, using precision fasteners, so that there is a defined relative position between divergence corrector 3″ and light source 2. In the present exemplary embodiment, substrate 11 of divergence corrector 3, on which structural surface 8 is arranged on the front side, adjoins housing 13 on the inner side. In the present exemplary embodiment, structural surface 8 is arranged projecting relative to housing 13. Divergence corrector 3″ or substrate 11 is arranged at a distance ‘a’ from light-emitting surface 10 of light source 2. The distance ‘a’ is at most 2 mm.

According to a further embodiment of the invention according to FIG. 4, a divergence corrector 3′″ is provided which differs from divergence corrector 3″ according to FIG. 3 in that substrate 11 does not include a crystal-clear substrate material but of a light-converting material 5, preferably a phosphor material, so that light source 2 itself need not have any light-converting material.

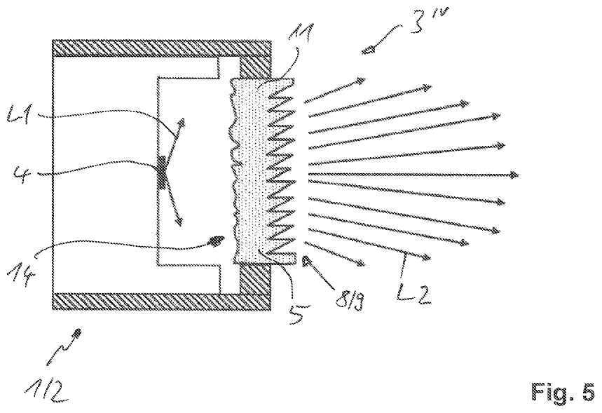

According to a further embodiment of the invention according to FIG. 5, a divergence corrector 3^{IV} is provided which, compared to divergence corrector 3′″, additionally has a surface structuring 14 on a side facing light source 2 (rear side) for the additional shaping of light beam L1 emitted by light-emitting diode 4. The surface structuring 14 has a different dimension than the front-side structural surface 8. Structural surface 8 serves exclusively to compensate for dispersion effects.

According to an alternative embodiment of the invention that is not shown, substrate 11 of divergence corrector 3^{IV} according to FIG. 5 can also be made of a crystal-clear material, therefore, without a light-converting effect.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An illumination device for vehicles, the illumination device comprising:
a housing that is adapted to be closed by a transparent cover panel;
a light source unit arranged in the housing, the light source unit adapted to generate a light beam;
an optical unit arranged in the housing to shape shaping the light beam according to a specified light distribution to be generated outside of the housing,
wherein the optical unit has a divergence corrector for the light beam,
wherein the divergence corrector, on a side facing away from the light source has a structural surface having a plurality of structural elements in the micro and/or nano and/or atomic length range, and
wherein the structural surface is arranged directly on or near to a light-emitting surface of the light source.

2. The illumination device according to claim 1, wherein the divergence corrector has a transverse extent to a main emission direction of the light source, which is equal to or at most 1.5 times a width of the light-emitting surface of the light source.

3. The illumination device according to claim 1, wherein the structural elements have a maximum height relative to a base area of the same in the micro and/or nano and/or atomic length range.

4. The illumination device according to claim 1, wherein the divergence corrector is arranged at a distance of at most 2 mm from the light-emitting surface of the light source.

5. The illumination device according to claim 1, wherein the divergence corrector has a substrate receiving the structural surface and having a thickness which is in a range between 1 mm and 5 mm.

6. The illumination device according to claim 1, wherein the structural surface of the divergence corrector forms the light-emitting surface of the light source.

7. The illumination device according to claim 1, wherein the substrate is arranged directly on the light-emitting surface of the light source or at a distance from the light-emitting surface of the light source or the light-emitting semiconductor element and wherein the structural surface is arranged on a side of the substrate, the side facing away from the light source.

8. The illumination device according to claim 1, wherein the divergence corrector has a housing which is fastened directly to a housing of the light source.

9. The illumination device according to claim 8, wherein the substrate of the divergence corrector is formed of a light-converting material.

10. The illumination device according to claim 8, wherein the divergence corrector has a surface structuring on a side facing the light source for the additional shaping of the light beam.

11. The illumination device according to claim 1, wherein the optical unit has a light guide and/or a lens device and/or a liquid crystal device and/or a microlens device and/or a device with one or a plurality of micromirrors, each of which is arranged in the light propagation direction towards the divergence corrector.
